(19) United States
(12) Patent Application Publication
(10) Pub. No.: US 2006/0012051 A1
(43) Pub. Date: Jan. 19, 2006

(54) Production process and production apparatus of three-dimensionally structured material

(75) Inventors: Koichi Sato, Atsugi-shi (JP); Ikuo Nakazawa, Kawasaki-shi (JP); Ryuji Higashi, Kawasaki-shi (JP); Sakae Suda, Yokohama-shi (JP); Masayuki Ikegami, Atsugi-shi (JP); Keiichiro Tsubaki, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/229,591

(22) Filed: Sep. 20, 2005

(30) Foreign Application Priority Data
Jan. 27, 2004 (JP) 2004-018877

(51) Int. Cl. H01L 23/52

(52) U.S. Cl. 257/777

(57) ABSTRACT

Disclosed herein is a process for producing a three-dimensionally structured material, which comprises the steps of preparing a liquid composition comprising a block polymer and a liquid medium, and imparting a stimulus to the liquid composition to modify the block polymer, thereby forming the three-dimensionally structured material.

### TECHNICAL FIELD

The present invention relates to a production process and a production apparatus of a three-dimensionally structured material, and particularly to a three-dimensional pattern-forming process or a three-dimensional shaping process used in a functional device-fabricating step, rapid prototyping or the like, and materials and apparatus thereof.

### BACKGROUND ART

In fabrication of devices making good use of micromechanics or fabrication of active devices heretofore used in semiconductors and display elements, a step of etching using spin coating and patterned exposure is conducted as a process for forming a steric three-dimensional pattern. It has also been recently known to directly form a three-dimensional pattern using minute ink-jet technology.

Technological development mainly for rapid prototyping with three-dimensional shaping technology using a stereolithographic technique or liquid-jet technique (see Japanese Patent Application Laid-Open No. H05-279436) is also increasingly conducted to develop technology for producing a larger molded object without using the so-called mold.

However, the above-described production process of a three-dimensionally structured material, such as the conventional three-dimensional pattern-forming process or three-dimensional shaping process, may be not yet sufficient in some cases from the viewpoint of cost or performance, and its use is limited to limited users. There is thus a demand for more improvement in technical level under these circumstances.

### DISCLOSURE OF THE INVENTION

The present invention has been made in view of the foregoing background art and has achieved as its object the provision of a process for easily producing a three-dimensionally structured material by modifying a liquid composition comprising a block polymer and a liquid medium.

Another object of the present invention is to provide an apparatus for producing a three-dimensionally structured material by modifying a liquid composition comprising a block polymer and a liquid medium.

A further object of the present invention is to provide a liquid composition comprising a modifiable block polymer and a liquid medium, and a three-dimensionally structured material formed from this composition.

In a first aspect of the present invention, there is thus provided a process for producing a three-dimensionally structured material, which comprises the steps of preparing a liquid composition comprising a block polymer and a liquid medium, and imparting a stimulus to the liquid composition to modify the block polymer, thereby forming the three-dimensionally structured material.

The process may preferably further comprise a step of solidifying the liquid composition after the modification of the block copolymer.

The block polymer may preferably be amphiphilic and form micelles.

The process may preferably further comprise a step of ejecting the liquid composition to form the three-dimensionally structured material.

A functional substance may preferably be included in the block polymer.

The block polymer may preferably have a repeating structure of a monomer unit composed of an alkenyl ether.

In a second aspect of the present invention, there is provided an apparatus for producing a three-dimensionally structured material, which comprises a means for imparting a stimulus to a liquid composition comprising a block polymer and a liquid medium to modify the block polymer, thereby forming the three-dimensionally structured material.

In a third aspect of the present invention, there is provided a liquid composition suitable for use in producing a three-dimensionally structured material, which comprises a block polymer modifiable by stimulus and a liquid medium.

In a fourth aspect of the present invention, there is provided a three-dimensionally structured material formed by a block polymer modifiable by stimulus.

According to the present invention, there can be provided a process for easily producing a three-dimensionally structured material by modifying a liquid composition comprising a block polymer and a liquid medium.

According to the present invention, there can also be provided an apparatus for producing a three-dimensionally structured material by modifying a liquid composition comprising a block polymer and a liquid medium.

According to the present invention, there can further be provided a liquid composition comprising a modifiable block polymer and a liquid medium, and a three-dimensionally structured material formed from this composition.

### BRIEF DESCRIPTION OF THE DRAWINGS

FIG. 1 schematically illustrates a three-dimensional pattern-forming process by a liquid-jet method according to the present invention.

FIG. 2 is a block diagram illustrating the construction of a liquid-jet recording apparatus.

### BEST MODE FOR CARRYING OUT THE INVENTION

The present invention will hereinafter be described in detail.

In the first aspect of the present invention, there is provided a process for shaping a three-dimensionally structured material using a modifiable liquid composition, which comprises modifying the liquid composition comprising a block polymer in a liquid medium.

A process for forming a steric three-dimensional pattern in fabrication of devices making good use of micromechanics or fabrication of active devices heretofore used in semiconductors and display elements, and three-dimensional shaping technology mainly for rapid prototyping with three-dimensional shaping technology using a stereolithographic technique or liquid-jet technique (Japanese Patent Application Laid-Open No. H05-279436) as technology for producing a larger molded object without using the so-called mold are representative of a shaping process using a modifiable liquid composition. In the present invention, a three-dimensional shaping process using the stereolithographic technique or liquid-jet technique is also preferably used. Stereolithographic apparatus, SCS-8000 and SCS-3000 manufactured by D-MEC LTD., and the like are known as specific examples of such stereolithographic methods and apparatus. Thermo-Jet 3D Printer, In-Vision 3D Printer and the like are known as three-dimensional shaping methods and apparatus by the so-called liquid-ejection method based on the ink-jet technology.

In such a three-dimensional object-shaping process using no mold, a three-dimensional object is formed by modifying and solidifying a liquid composition by light or any other external field. As a typical example in the stereolithography, a photo-curable liquid composition is filled in a bath, a laser beam or ultraviolet ray is applied to a portion to form an intended three-dimensional object to cure the liquid composition of this portion, thereby forming a cured three-dimensional object, and a peripheral uncured portion of the liquid composition is removed, whereby the intended three-dimensional object can be obtained. A feature of the present invention resides in that a liquid composition comprising a block polymer, which is also called a block copolymer, as a component in such a liquid composition is used.

The block polymer used in the present invention is a polymer called a block polymer or block copolymer, in which polymers of different segment structures are bonded into a chain by a covalent bond. In the present invention, a graft polymer may also be used. The graft polymer is such a polymer that polymers of different segment structures are covalently bonded in the form of a character ‘T.’ Specific examples of the block polymer usable in the present invention include conventionally known block polymers such as acrylic or methacrylic block polymers, block polymers composed of polystyrene and any other addition polymerization system or condensation polymerization system, and block polymers having blocks of polyoxyethylene, polyoxyalkylene, polyalkenyl ether or the like. In the present invention, the block copolymer is more preferably in a block form of AB, ABA, ABD or the like. A, B and D indicate block segments different from one another.

In the present invention, the block copolymer may be such a graft polymer that another polymer is boned in the form of a character ‘T’ to a certain polymer chain. Each segment of the block polymer may be a copolymer segment, and the copolymer form thereof may be, for example, a random segment or graduation segment.

The present inventors have carried out an extensive investigation repeatedly. As a result, it has been found that when a liquid composition comprising the block polymer is used in the above-described shaping method, modifiable properties derived from the block polymer are utilized, a three-dimensional pattern can be formed with extremely good results. Since the block polymer has different 2 or more block segments, functional separation between physical properties or characteristics of respective segments is clearly made, and so it is suitable for use as various functional materials. In particular, when the liquid composition is used in the above-described shaping method, extremely excellent properties or characteristics can be exhibited, and an excellent three-dimensional pattern-forming process can be realized.

It is preferable that an amphiphilic block polymer be used to use a micelle structure formed by this polymer at least either before or after the modification. It goes without saying that the micelle structure may be used both before and after the modification. The micelle structure is preferably formed at the time the liquid composition has been modified or solidified into a three-dimensional object or in the course of conversion into the three-dimensional object. The present inventors have also found that when the micelle state is utilized upon the formation of a three-dimensional object has been formed, its characteristic viscoelastic properties are extremely suitable for the formation of the three-dimensional object.

A preferable range for the viscoelastic properties in formation of the three-dimensional object is from 10⁻¹ to 10⁸ Pa for G′ (storage modulus) and from 10⁻¹ to 10⁸ Pa for G″ (loss modulus), and a more preferable range is from 10² to 10⁷ Pa for G′ and from 10² to 10⁷ Pa for G″. If both G′ and G″ exceed 10⁸ Pa in formation of the three-dimensional object, only a three-dimensional object in a distorted form may be formed in some cases. If both G′ and G″ are lower than 10⁻¹ Pa, no three-dimensional object may be formed in some cases. Conditions of G′≧G″ are preferably used. G′ and G″ may be generally measured by a viscoelastometer, or the so-called rheometer. These viscoelastic properties appear in the course of the modification. The liquid composition may have the viscoelastic properties in all the course of the modification, or a state having these viscoelastic properties may be temporally formed. Both G′ and G″ of the liquid composition before the modification are preferably one hundredths or lower, more preferably one thousandths or lower of the above-described respective ranges.

The micelle referred to in the present invention may be normal micelles in a water-based solvent or reversed micelles in an organic solvent. In the present invention, the micelle is defined as a micelle taken in a wide sense. When a self-accumulating phase-separated higher-order structured material is formed in a solvent by having both solvophilic and solvophobic segments, such a structured material is regarded as a micelle. In other words, when a block polymer having a segment soluble in, for example, toluene and a segment insoluble therein is dispersed in toluene, a structured material, in which a solvophilic portion and a solvophobic portion undergo phase separation, is formed. Such a structured material is also regarded as a micelle in the present invention. In a narrow sense, it may also be interpreted that the presence of water is indispensable both for the normal micelle and the reversed micelle. In the present invention, however, such a standpoint is not taken. The form of the micelle referred to in the present invention may be any of spherical, elliptical, cylindrical and lamellar forms.

A structured material in which a functional substance is adsorbed on and coated with a solvophilic portion of an amphiphilic block polymer, i.e., a coated functional substance structured material is also suitably used in the present invention. This coated functional substance structured material may be considered a micelle in a wide sense. The functional substance in the present invention may be any form of solid, powder and liquid and means a compound or composition exhibiting a desired function. As examples thereof, may be mentioned agricultural chemicals such as herbicides and insecticides, medicaments such as anti-cancer drugs, anti-allergic drugs and antiphlogistics, and coloring materials, typically, dyes and pigments. Examples of the agricultural chemicals include active compounds having a herbicidal effect and active compounds having an insecticidal effect. Examples of the medicaments include compounds easing or remitting a target condition. The present invention is particularly effective when the functional substance is a coloring material. When such a three-dimensional object as described above is produced, multi-color, preferably full-color representation becomes feasible, and so the use of the coloring material as the functional substance is highly useful. As specific examples of the coloring material, may be mentioned particulate solids such as pigments, and dye compounds.

As described above, examples of the coloring material include pigments. Examples of the pigments include inorganic achromatic pigments and organic or inorganic chromatic pigments. Colorless or light-colored pigments and metalescent pigments may also be used. Pigments newly synthesized for the present invention may also be used. Examples of the pigments are mentioned below.

As examples of black pigments, may be mentioned Raven 1060 (trade name, product of Columbian Carbon Co.), Black Pearls L, MOGUL-L, Regal 400R, Regal 660R and Regal 330R (trade name, products of Cabot Company), Color Black FW1 and Printex 140V (trade name, products of Degussa AG), and MA100 (trade name, product of Mitsubishi Chemical Corporation). However, the present invention is not limited thereto.

As examples of cyan pigments, may be mentioned C.I. Pigment Blue 1, C.I. Pigment Blue 2, C.I. Pigment Blue 3 and C.I. Pigment Blue 15. However, the present invention is not limited thereto.

As examples of magenta pigments, may be mentioned C.I. Pigment Red 5, C.I. Pigment Red 7 and C.I. Pigment Red 12. However, the present invention is not limited thereto.

As examples of yellow pigments, may be mentioned C.I. Pigment Yellow 12, C.I. Pigment Yellow 13, C.I. Pigment Yellow 14, C.I. Pigment Yellow 16, C. I. Pigment Yellow 17 and C.I. Pigment Yellow 74. However, the present invention is not limited thereto.

In the present invention, dyes may also be used like the pigments.

The dyes usable in the present invention may be either publicly known or novel, and water-soluble dyes such as direct dyes, acid dyes, basic dyes, reactive dyes and food dyes, fat-soluble (oil-soluble) dyes, and insoluble colorants such as disperse dyes as described below may be used. These dyes may also be used in a solid state. Regarding this, for example, oil-soluble dyes are preferably used.

Examples thereof include C.I. Solvent Blue 33, 38, 42, 45, 53, 65, 67, 70, 104, 114, 115 and 135; C.I. Solvent Red 25, 31, 86, 92, 97, 118, 132, 160, 186, 187 and 219; C.I. Solvent Yellow 1, 49, 62, 74, 79, 82, 83, 89, 90, 120, 121, 151, 153 and 154.

Water-soluble dyes may also be used. Examples thereof include

direct dyes such as C.I. Direct Black 17; C.I. Direct Yellow 12 and 24; C.I. Direct Red 1, 4 and 13; C.I. Direct Blue 6, 22 and 25; C.I. Direct Orange 34 and 39; C.I. Direct Violet 47 and 48; C.I. Direct Brown 109; and C.I. Direct Green 59, acid dyes such as C.I. Acid Black 2 and 7; C.I. Acid Yellow 11 and 17; C.I. Acid Red 1, 6 and 8; C.I. Acid Blue 9 and 22; C.I. Acid Orange 7 and 19; and C.I. Acid Violet 49,

reactive dyes such as C.I. Reactive Black 1 and 5; C.I. Reactive Yellow 2 and 3; C.I. Reactive Red 3 and 13; C.I. Reactive Blue 2 and 3; C.I. Reactive Orange 5 and 7; C.I. Reactive Violet 1, 4 and 5; C.I. Reactive Green 5 and 8; and C.I. Reactive Brown 2 and 7, and

C.I. Basic Black 2; C.I. Basic Red 1 and 2; C.I. Basic Blue 1, 3 and 5; C.I. Basic Violet 7, 14 and 27; and C.I. Food Black 1 and 2.

Incidentally, the examples of the coloring materials mentioned above are particularly preferred for the compositions according to the present invention. However, the coloring materials used in the present invention are not particularly limited to the coloring materials mentioned above.

When a functional substance is used, the functional substance is preferably contained in the liquid composition in a range of from 0.01 to 80% by mass based on the whole mass of the liquid composition. When two or more functional substances are used, the total amount thereof is preferably set so as to fall within the above-described range. When the amount of the functional substances is not less than 0.01% by mass, a sufficient function is achieved. When the amount is not more than 80% by mass, good dispersibility is achieved. The amount is preferably within a range of from 0.1% by mass to 50% by mass, more preferably from 0.3% by mass to 30% by mass. In a preferred embodiment of the present invention, the functional substance is used in such a state as being coated with and included in the amphiphilic block polymer. However, it may not be necessarily coated and included.

In the present invention, it is a preferred use mode to use a micelle state formed by the amphiphilic block polymer. In this state, a very preferable effect can be exhibited in the formation of the three-dimensional object as described above. However, it is particularly preferably used in conducting three-dimensional imaging of a multi-color object using plural kinds of liquid compositions containing a coloring material. In other words, an excellent multi-color three-dimensionally imaged object can be provided. There have heretofore arisen such problems that color mixing occurs upon conducting multi-color imaging and that when different colors overlap with each other, a portion of a first color must be subjected to a solidifying treatment over a sufficient period of time before the next color is formed for the purpose of preventing color mixing. According to the present invention, however, the color mixing can be inhibited very well. In the case of stereolithography, a bath treatment must be typically conducted for every color. In a direct shaping process such as the liquid-jet, a color is subjected to a solidifying treatment over a sufficient period of time, and a three-dimensional object of a next color is then formed. However, the present invention is applied, whereby multi-color imaging improved in color mixing can be preferably conducted without taking such a too excess time in a liquid-jet process in particular. On the other hand, such effect to inhibit color mixing cannot be explained by the viscoelastic properties alone. However, it is considered to relate to the fact that a coloring material is formed by uniform micelle particles of from several tens nanometers to submicrons.

In the present invention, a block polymer containing a polyalkenyl ether structure is preferably used as a block polymer compound. A block polymer containing a polyvinyl ether structure is particularly preferred. A great number of synthetic processes of the block polymer containing the polyalkenyl ether structure used preferably in the present invention have been reported. A process by cationic living polymerization by Aoshima et al. (Journal of Polymer Bulletin, Vol. 15, p. 417, 1986; Japanese Patent Application Laid-Open No. H11-322942) is representative thereof. By conducting polymer synthesis by the cationic living polymerization, various polymers such as homopolymers, copolymers composed of two or more monomers, block polymers, graft polymers and graduation polymers can be synthesized with their chain lengths (molecular weights) exactly made uniform. In the polyalkenyl ether, various functional groups may be introduced in its side chains. Besides, the cationic polymerization may also be conducted in an HI/I₂ system, HCl/SnCl₄ system or the like.

The structure of the block polymer containing the polyalkenyl ether structure may be a copolymer composed of vinyl ether and another polymer.

The block polymer containing the polyvinyl ether structure preferably used preferably has a repeating unit structure represented by the following general formula (1): 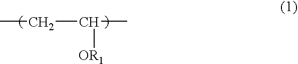
wherein R₁ is selected from a linear, branched or cyclic alkyl group having 1 to 18 carbon atoms, —(CH(R₂)—CH(R₃)—O)₁—R₄ and —(CH₂)ₘ—(O)ₙ—R₄, in which 1 and m are, independently of each other, selected from integers of from 1 to 12, n is 0 or 1, R₂ and R₃ are, independently of each other, hydrogen or CH₃, and R₄ is hydrogen, a linear, branched or cyclic alkyl group having 1 to 6 carbon atoms, —Ph, —Pyr, —Ph—Ph, —Ph—Pyr, —CHO, —CH₂CHO, —CO—CH═CH₂, —CO—C(CH₃)═CH₂ or —CH₂COOR₅, with the proviso that when R₄ is any other group than hydrogen, hydrogen bonded to carbon may be substituted by a linear or branched alkyl group having 1 to 4 carbon atoms, F, Cl, Br, carboxylic acid, or carboxylic acid salt, or carbon in the aromatic ring may be substituted by nitrogen, and R₅ is hydrogen or an alkyl group having 1 to 5 carbon atoms.

In the above, —Ph, —Pyr, —Ph—Ph and —Ph—Pyr denote a phenyl, pyridyl, biphenyl and pyridylphenyl groups, respectively. With respect to the pyridyl, biphenyl and pyridylphenyl groups, they may be any possible position isomers.

An amphiphilic block polymer can be obtained by, for example, conducting synthesis by selecting a hydrophobic block segment and a hydrophilic block segment from the repeating unit structures of the general formula (1). In the case of the graft polymer, an amphiphilic polymer can be obtained by, for example, grafting a hydrophobic polymer segment on a hydrophilic polymer.

As examples of specific repeating units of the hydrophilic block segment, the segment preferably has a repeating unit structure represented by the following general formula (2): 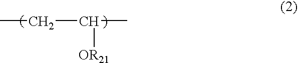
wherein R₂₁ is selected from —(CH(R₂)—CH(R₃)—O)₁—R₄ and —(CH₂)ₘ—(O)ₙ—R₄, in which 1 and m are, independently of each other, selected from integers of from 1 to 12, n is 0 or 1, R₂ and R₃ are, independently of each other, hydrogen or CH₃, and R₄ is hydrogen, a linear, branched or cyclic alkyl group having 1 to 6 carbon atoms, or an aliphatic or aromatic carboxylic acid or carboxylic acid salt.

Preferable examples of the specific repeating units of the hydrophilic block segment include the following units: 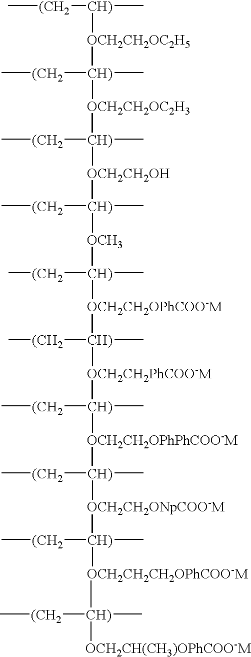
wherein Ph is 1,4-phenylene or 1,3-phenylene, Np is 2,6-naphthylene, 1,4-naphthylene or 1,5-naphthylene, and M is a monovalent or polyvalent cation, with the proviso that when M is a polyvalent cation, a counter anion also takes a form corresponding to the cation.

As examples of specific repeating units of the hydrophobic block segment, the segment preferably has a repeating unit structure represented by the following general formula (3): 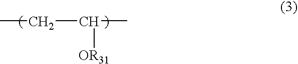
wherein R₃₁ is selected from a linear, branched or cyclic alkyl group having 1 to 18 carbon atoms, —(CH(R₂)—CH(R₃)—O)₁—R₄ and —(CH₂)ₘ—(O)ₙ—R₄, in which 1 and m are, independently of each other, selected from integers of from 1 to 12, n is 0 or 1, R₂ and R₃ are, independently of each other, hydrogen or CH₃, and R₄ is a linear, branched or cyclic alkyl group having 1 to 6 carbon atoms, —Ph, —Pyr, —Ph—Ph, —Ph—Pyr, —CHO, —CH₂CHO, —CO—CH═CH₂, —CO—C(CH₃)═CH₂ or —CH₂COOR₅, with the proviso that hydrogen bonded to carbon may be substituted by a linear or branched alkyl group having 1 to 4 carbon atoms, F, Cl, or Br, or carbon in the aromatic ring may be substituted by nitrogen, and R₅ is an alkyl group having 1 to 5 carbon atoms.

Preferable examples of the specific repeating units of the hydrophobic block segment include the following units: 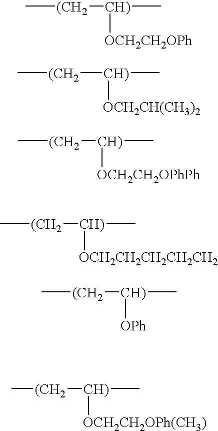
wherein Ph is 1,4-phenylene or 1,3-phenylene, and Np is 2,6-naphthylene, 1,4-naphthylene or 1,5-naphthylene.

The molecular weight distribution Mw (weight average molecular weight)/Mn (number average molecular weight) of the block polymer used in the present invention is preferably 2.0 or lower, more preferably 1.6 or lower, still more preferably 1.3 or lower, still further preferably 1.2 or lower.

The number average molecular weight (Mn) of the block polymer or graft polymer used in the present invention is preferably 200 or higher, preferably 3,000 or higher, but preferably does not exceed 1,000,000. When the number average molecular weight is 200 or higher, the dispersion stability of the functional substance is improved. In the present invention, the number average molecular weight and weight average molecular weight of a polymer can be measured by volume exclusion chromatography (another name: gel permeation chromatography/GPC).

The content of the block copolymer or graft polymer contained in the liquid composition according to the present invention is from 0.1% by mass to 90% by mass, preferably from 1% by mass to 50% by mass. When the content is at least 0.1% by mass, the functional substance is dispersed or dissolved in the liquid composition in a sufficient state. When the content is not higher than 90% by mass, the viscosity of the resulting liquid composition becomes moderate. It is hence preferable to contain the block polymer or graft polymer within the above-described range.

The liquid composition according to the present invention contains a liquid medium. No particular limitation is imposed on the liquid medium contained in the liquid composition according to the present invention. The liquid medium means a liquid medium in which components to be contained in the liquid composition can be dissolved, suspended or dispersed. In the present invention, water-insoluble organic solvents such as various kinds of linear, branched and cyclic aliphatic hydrocarbons, aromatic hydrocarbons, and heterocyclic aromatic hydrocarbons, water-soluble organic solvents, and water may be used as the liquid medium. It goes without saying that a mixed solvent thereof may be used.

A water-based liquid medium used in the liquid composition according to the present invention is water or a hydrophilic liquid medium composed of water and a water-soluble organic solvent.

Examples of the water-soluble organic solvent include polyhydric alcohols such as ethylene glycol, diethylene glycol, triethylene glycol, polyethylene glycol, propylene glycol, polypropylene glycol and glycerol, polyhydric alcohol ethers such as ethylene glycol monomethyl ether, ethylene glycol monoethyl ether, ethylene glycol monobutyl ether, diethylene glycol monoethyl ether and diethylene glycol monobutyl ether, and nitrogen-containing solvents such as N-methyl-2-pyrrolidone, substituted pyrrolidone and triethanolamine. A monohydric alcohol such as methanol, ethanol or isopropanol may also be used. A water-soluble polymerizable compound may also be contained. Examples thereof include hydroxyethylacrylic acid, hydroxyethyl-methacrylic acid and styrenesulfonic acid. A crosslinking agent may also be used at the same time. Two or more of those described above may be used in combination as needed.

As an organic liquid medium used in the liquid composition according to the present invention, may be used, for example, toluene, hexane, heptane, nonane, an acetate, or a monohydric alcohol such as methanol, ethanol or isopropyl alcohol. Methacrylates, acrylates, styrene and the like may also be mentioned. A crosslinking agent may also be used at the same time. Two or more of those described above may be used in combination as needed.

The content of the liquid medium used in the liquid composition according to the present invention may be selected from a range of from 0.9% by mass to 99% by mass, and it is preferably from 10% by mass to 99% by mass. When the content is not lower than 0.1% by mass, the viscosity of the resulting liquid composition becomes moderate. When the content is not higher than 99% by mass, the function of the polymer can be sufficiently exhibited.

As the block polymer characteristically used in the present invention, at least two amphiphilic polymers may also be used in combination in the same liquid composition as needed.

The functional substance contained in the liquid composition is preferably included in the block polymer or graft polymer for the purpose of inhibiting modification caused by attack from an external environment (typically, for improving weatherability). The block polymer or graft polymer is effective in that it can easily include the functional substance therein by forming a self-accumulating structure. In order to improve the dispersion stability and inclusion property of the functional substance, the molecular motion of the block polymer or graft polymer is preferably more flexible because such a polymer is likely to physically entangle with the surface of the functional substance and have affinity for it. The polymer may also be preferably flexible from the viewpoint of easy formation of a coating layer on a recording medium as described in detail below. Therefore, the glass transition temperature Tg of the main chain of the block polymer is preferably 20° C. or lower, more preferably 0° C. or lower, still more preferably −20° C. or lower. In this regard, a polymer having a polyvinyl ether structure is preferably used because it has properties of a low glass transition point and is flexible. In this sense, the block polymer having the polyvinyl ether structure may also be preferably used.

The functional substance is preferably included in the liquid composition according to the present invention. The included state can be formed by, for example, adding a solution of a coloring material in an organic solvent insoluble in water to a micelle formed by the block polymer or graft polymer in water and then distilling off the organic solvent. Besides, it may also be formed by forming an inclusion state by conducting phase inversion into a hydrophilic solvent from a state that both block polymer or graft polymer and coloring material have been dissolved in an organic solvent, and distilling off the remaining organic solvent. The confirmation of the included state can be performed by various kinds of electron microscopes and/or instrumental analyses such as X-ray diffraction. In the case of inclusion in a micelle state, the included state can be indirectly confirmed by separation of the coloring material from the solvent independently of the polymer under conditions of micelle collapse.

As described above, the block polymer or graft polymer preferably forms a micelle state. Therefore, it is effective that the block polymer or graft polymer used in the present invention is amphiphilic. In this sense, the block polymer or graft polymer preferably has a polymer segment having an ionic repeating unit structure. In the present invention, the block polymer is preferably used from the viewpoints of dispersion-stability, inclusion of the functional substance and various properties, such as viscosity.

The proportion of the functional substance included in the block polymer or graft polymer of the functional substance contained in the liquid composition is preferably 90% by mass or higher, more preferably 95% by mass or higher, still more preferably 98% by mass or higher based on the whole mass of the functional substance. This quantitative proportion can also be observed by various kinds of electron microscopes, instrumental analyses such as X-ray diffraction, or coloring density analysis when the functional substance is a coloring material, or by the indirect method described above.

Besides the above components, various kinds of modifiers or additives such as antioxidants, viscosity modifiers, ultraviolet absorbents, surfactants and mildewproofing agents may be added to the liquid composition according to the present invention.

In the present invention, plural kinds of liquid compositions may also be used in combination to shape a three-dimensional object. As described above, the multi-color three-dimensional imaging is an example thereof. A three-dimensionally structured material composed of plural kinds of layers different in not only color species but also properties can also be produced. For example, a three-dimensional object may be formed by alternately stacking layers different in modulus or strength to produce a three-dimensional object having both properties that are not necessarily matched to each other, i.e., high modulus and excellent impact resistance. A multi-color three-dimensional object may also be produced. When a three-dimensional pattern is formed using such plural kinds of liquid compositions, it is preferable that plural kinds of liquid compositions containing the block polymer according to the present invention be used, at least one of the liquid compositions be a water-based liquid composition, and at least one of the other liquid compositions be an oil-based liquid composition in that a three-dimensional object improved in mixing of 2 liquids (2 colors) can be produced. All the liquid compositions used do not always contain the block polymer, only one of them may be a liquid composition containing the block polymer.

In the present invention, the liquid composition described above is modified to produce a three-dimensional object. Some stimulus to be a trigger for modification is imparted to facilitate the modification, thereby solidifying the liquid composition to produce the three-dimensional object. The polymer-containing composition according to the present invention can respond to various stimuli to modify its state (properties). As example of “stimuli” in the present invention, may be mentioned temperature change; application of an electric field; exposure to light (electromagnetic wave) such as ultraviolet light, visible light or infrared light; pH change of the composition; addition of a chemical substance; and concentration change of the composition. These stimuli may preferably be used in combination.

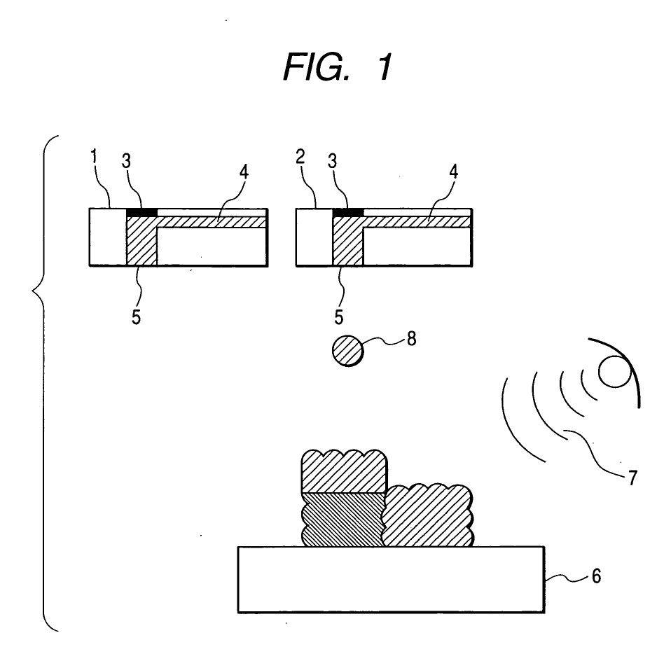

A specific example of a three-dimensional pattern-forming process for a three-dimensionally structured material according to the present invention is illustrated in FIG. 1. FIG. 1 illustrates a three-dimensional pattern-forming process by a liquid-jet method. Reference numerals 1 and 2 indicate liquid-jet devices typically illustrated. The liquid-jet device is basically the same device as an ink-jet device of digital printing technology. A liquid is ejected by a drive device 3 to form a pattern. The thermal-jet or the piezo-jet is representative of the drive device 3. The liquid-jet device may be a continuous liquid-jet device that does not carry out on-demand driving. Reference numerals 4, 5 and 6 are a liquid feed passage, a liquid ejection opening and a substrate on which a three-dimensional object is formed, respectively.

As a specific three-dimensional pattern-forming process, the liquid-jet devices 1, 2 are used as liquid-jet devices of the heat retaining type. Two compositions are used as the liquid compositions. One is a blue-pigment-including liquid composition containing a block polymer of which the viscosity and the elasticity at a temperature not higher than 60° C. increase 3,000 times compared with those at a temperature higher than that, and the other is a yellow pigment-including liquid composition containing a block polymer of which the viscosity and the elasticity at a temperature not higher than 60° C. increase 4,000 times compared with those at a temperature higher than that. The blue liquid composition is first ejected on a desired pattern from a head of the liquid-jet device 1 retained to a temperature of 80° C. and primarily solidified by increase in viscosity and elasticity attending on temperature drop before and after impact on the substrate after the ejection, thereby forming a three-dimensional basic pattern, during which electromagnetic waves 7, typically ultraviolet rays, are continuously irradiated to complete the crosslinking and solidification of the polymer. Before long, the yellow liquid composition is ejected from a head of the liquid-jet device 2 in the same manner as in the head of the liquid-jet device 1 to form a pattern. In such a manner, a three-dimensional object is easily formed because the characteristic block polymer according to the present invention is used. In addition, color mixing is markedly improved. In order to effectively develop the feature of the present invention as described above, a combination of plural stimuli such as thermal stimulus and electromagnetic wave stimulus is preferably used. Specifically, one of the stimuli is preferably electromagnetic wave stimulus in that it can be imparted with no contact. In the present invention, however, it is only necessary to use modification by at least one stimulus, and it is not essential to conduct modification by plural kinds of stimuli.

The present invention may also be applied to fabricating processes for micromechanic devices, semiconductor devices, TFT, and display devices such as an organic EL.

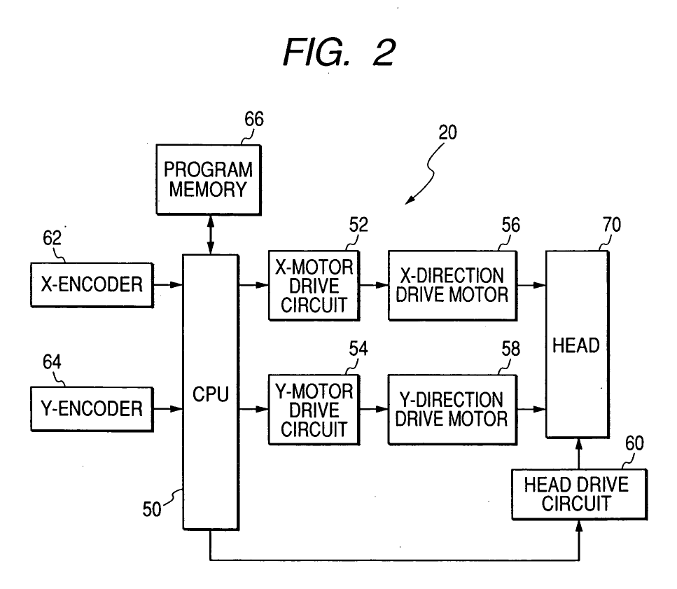

FIG. 2 is a functional diagram schematically illustrating a liquid-jet recording apparatus. Reference numeral 50 indicates a central processing unit (CPU) of the liquid-jet recording apparatus 20. A program for controlling the CPU 50 may be stored in a program memory 66 or may also be stored in a memory means such as EEPROM (not illustrated) as the so-called firmware. According to the liquid-jet recording apparatus, recording data is received from a recording data-preparing means (not illustrated, computer or the like) to the program memory 66. The recording data may be information itself of a three-dimensional object to be recorded, compressed information thereof or encoded information. When the compressed or encoded information is processed, expansion or development can be conducted by the CPU 50 to obtain the information of images or characters to be recorded. An X-encoder 62 (for example, relating to an X-direction or main scanning direction) and a Y-encoder 64 (for example, relating to a Y-direction or secondary scanning direction) can be provided to notify a relative position of a head to a substrate as a recording medium to the CPU 50.

The CPU 50 sends signals for recording a three-dimensional image to an X-motor drive circuit 52, a Y-motor drive circuit 54 and a head drive circuit 60 on the basis of the information of the program memory 66, X-encoder 62 and Y-encoder 64. The X-motor drive circuit 52 and Y-motor drive circuit 54 drive an X-direction drive motor 56 and a Y-direction drive motor 58, respectively, to move a head 70 relatively to the substrate and to a recording position. The head drive circuit 60 sends signals for conducting ejection of various kinds of liquid compositions to the head 70 at the time the head 70 has been moved to the recording position, thereby conducting recording. The head 70 may be a head for ejecting a single liquid composition or a head for ejecting plural kinds of liquid compositions.

The present invention will hereinafter be described in detail by the following examples. However, the present invention is not limited to these examples.

### EXAMPLE 1

<Block Polymer 1 Used>

Synthesis of triblock polymer composed of isobutyl vinyl ether (IBVE; block A), 2-(2-ethoxyethyl)oxyethyl vinyl ether (EOEOVE; block B) and ethyl 4-(2-vinyloxy)ethoxy-benzoate (VEOEtPhCOOEt; block C):

After the interior of a glass container equipped with a three-way stop-cock was purged with nitrogen, the container was heated to 250° C. under a nitrogen gas atmosphere to remove adsorbed water. After the system was returned to room temperature, 12 mmol of IBVE, 16 mmol of ethyl acetate, 0.05 mmol of 1-isobutoxyethyl acetate and 11 ml of toluene were added to cool the reaction system. At the time the temperature within the system had reached 0° C., 0.2 mmol of ethylaluminum sesquichloride (equimolar mixture of diethylaluminum chloride and ethylaluminum dichloride) was added to initiate polymerization. The molecular weight was periodically monitored by means of gel permeation chromatography (GPC) to confirm completion of the polymerization of a block A.

Then, 18 mmol of a monomer of a block B was added to continue the polymerization. After completion of the polymerization of the block B was confirmed by monitoring by means of GPC, a toluene solution of 10 mmol of a component of a block C was added to continue the polymerization. After 20 hours, the polymerization reaction was terminated. The termination of the polymerization reaction was conducted by adding a 0.3% by mass aqueous solution of ammonia/methanol into the system. The reaction mixture solution was diluted with dichloromethane and washed 3 times with 0.6 M hydrochloric acid and then 3 times with distilled water. The resultant organic phase was concentrated and dried to solids by an evaporator, and the residue was vacuum-dried. The resultant product was dialyzed repeatedly in a methanol solvent using a semi-permeable membrane composed of cellulose to remove monomeric compounds, thereby obtaining the intended triblock polymer. The identification of the compound was conducted by means of NMR and GPC. Mn was 50,600, and Mw/Mn was 1.34. The polymerization ratio of A to B to C was 200:300:30.

The block polymer thus obtained was hydrolyzed in a mixed solution of dimethylformamide and aqueous sodium hydroxide, whereby the block C component was hydrolyzed to obtain a triblock polymer in the form of a sodium salt. The identification of the compound was conducted by means of NMR and GPC.

This polymer was neutralized with 0.1N hydrochloric acid in an aqueous dispersion to obtain a triblock polymer, in which the block C component turned into a free carboxylic acid. The identification of the compound was conducted by means of NMR and GPC.

<Block Polymer 2 Used>

Block Polymer 2 was obtained by copolymerizing 2 mol % of 2-vinyloxyethyl methacrylate with the monomer of the segment B of Block Polymer 1.

<Liquid Composition>

One hundred parts by mass of Block Polymer 1 in the form of a carboxylate obtained above and 20 parts by mass of Oil Blue N (trade name, C.I. Solvent Blue 14, product of Aldrich Co.) were both dissolved in 250 parts by mass of THF and 80 parts by mass of ethylene glycol, the resultant solution was inverted into a water phase with 1,000 parts by mass of distilled water, and water was distilled off under pressure to reduce the amount of the liquid, thereby obtaining Liquid Composition (1). Even when the ink composition thus obtained was left to stand for 10 days at room temperature, neither separation nor precipitation occurred.

Liquid Composition (2) was prepared in the same manner as in the preparation of Liquid Composition (1) except that the coloring material was changed to C.I. Pigment Blue 15:3. Even when the ink composition thus obtained was left to stand for 10 days at room temperature, neither separation nor precipitation occurred.

Liquid Composition (3) was prepared in the same manner as in the preparation of Liquid Composition (1) except that the coloring material was changed to a yellow oil-soluble dye (VALIFAST YELLOW 3108, trade name, product of Orient Chemical Industries Ltd.). Even when the ink composition thus obtained was left to stand for 10 days at room temperature, neither separation nor precipitation occurred.

Liquid Composition (4) was prepared in the same manner as in the preparation of Liquid Composition (1) except that Block Polymer 2 in the form of a carboxylate obtained above was used, a yellow oil-soluble dye (VALIFAST YELLOW 3108, trade name, product of Orient Chemical Industries Ltd.) was used as the coloring material, and 3 parts by mass of a photo-polymerization initiator (IRGACURE 184, trade name, product of Ciba-Geigy Limited) was added.

G′ and G″ of Liquid Compositions (1) to (4) at 80° C. and 0° C. are shown in the following Table 1. The measurement was conducted by means of Rheometer DAR100 (trade name, manufactured by Rheologica Instruments) by applying sinusoidal oscillation of 1 Hz.

TABLE 1

| | |
|---|---|
| 80° C. | 0° C. |

| | G′ (Pa) | G″ (Pa) | G′ (Pa) | G″ (Pa) |
|---|---|---|---|---|
| Liquid | 0.012 | 0.009 | 8,142 | 1,320 |
| Composition (1) | | | | |
| Liquid | 0.008 | 0.010 | 12,290 | 4,578 |
| Composition (2) | | | | |
| Liquid | 0.010 | 0.009 | 9,788 | 5,544 |
| Composition (3) | | | | |
| Liquid | 0.010 | 0.010 | 10,234 | 2,320 |
| Composition (4) | | | | |

Each of Liquid Compositions (1) to (4) was adjusted to pH 2 with diluted hydrochloric acid at 80° C. As a result, colored micelle particles were precipitated. A supernatant obtained by removing the particles by centrifugation was colorless. With respect to the density ratio in terms of the intensity ratio at λmax between the ink composition and the decolored water phase, the absorbancy of the supernatant was lower than the detection limit. From this fact, it was found that the coloring material was completely included in the block polymer micelle.

<Production of Three-Dimensional Object>

A heater was installed in a head part of an ink-jet printer (BJC-800J, trade name, manufactured by Canon Inc.) to control the head part within a range of 80° C.±4° C. using a thermocouple. A cover was removed from the printer to arrange a silane-coupling-agent-coated stainless substrate having a thickness of 0.3 mm, which was a recording medium, with a distance of 20 mm from the head. The substrate was held at 0° C. Liquid Composition (4) was charged into an ink tank to conduct recording 2,500 times in the whole region of 1 mm×5 mm while being irradiated with ultraviolet light of about 2 mW/cm² with a central wavelength of 365 nm at a time duty of 4% and 0.1 Hz, thereby producing a three-dimensional object A. The three-dimensional object A thus obtained had an average width of 1.22 mm, an average length of 5.45 mm and an average height of 9.55 mm.

Liquid Composition (1) was used to produce a three-dimensional object B in the same manner as described above. The three-dimensional object thus obtained had an average width of 1.26 mm, an average length of 5.99 mm and an average height of 7.55 mm. G′ and G″ of this three-dimensional object were measured in accordance with the method described above and were found to be 18,442 Pa and 8,541 Pa, respectively.

Liquid Compositions (2) and (3) were respectively used to produce three-dimensional objects C and D in the same manner as in Liquid Composition (1), so that similar three-dimensional objects could be produced.

Just after the production of the three-dimensional object B, Liquid Composition (4) was applied on the object with the same pattern to produce a three-dimensional object. The three-dimensional object thus obtained had an average width of 1.23 mm, an average length of 5.67 mm and an average height of 18.44 mm. Color mixing between blue and yellow colors was scarcely observed. The color mixing thickness at the portion where the most severe color mixing was observed was at most 0.05 mm.

### Comparative Example 1

Water, acrylic acid and 2-hydroxyethyl acrylate were mixed in a mass ratio of 68:12:20 (in terms of parts by mass). To this mixture were added 1 part by mass of a photo-polymerization initiator (IRGACURE 184, trade name, product of Ciba-Geigy Limited) and 3 parts by mass of C.I. Direct Yellow 12, thereby preparing Liquid Composition a. Liquid Composition β was also prepared in the same manner as described above except that the coloring material was changed to C.I. Direct Red 1. A two-color three-dimensional object was produced in the same manner as in EXAMPLE 1 except that Liquid Compositions α and β were used. However, severe color mixing between yellow and red colors was observed, and the whole thereof turned orange.

According to the process and apparatus of the present invention for producing a three-dimensionally structured material, the three-dimensionally structured material can be easily produced by modifying a liquid composition comprising a block polymer and a liquid medium, so that they can be utilized in a process for forming a steric three-dimensional pattern in fabrication of devices making good use of micromechanics or active devices used in semiconductors and display elements.

This application claims priority from Japanese Patent Application No. 2004-018877 filed on Jan. 27, 2004, which is hereby incorporated by reference herein.

1. A process for producing a three-dimensionally structured material, which comprises the steps of preparing a liquid composition comprising a block polymer and a liquid medium, and imparting a stimulus to the liquid composition to modify the block polymer, thereby forming the three-dimensionally structured material.

2. The production process according to claim 1, which further comprises a step of solidifying the liquid composition after the modification of the block copolymer.

3. The production process according to claim 1, wherein the block polymer is amphiphilic and forms micelles.

4. The production process according to claim 1, wherein the stimulus to the liquid composition is selected from temperature change, application of an electric field, exposure to electromagnetic wave, pH change, addition of a chemical substance, and concentration change.

5. The production process according to claim 1, which further comprises a step of ejecting the liquid composition to form the three-dimensionally structured material.

6. The production process according to claim 1, wherein a functional substance is included in the block polymer.

7. The production process according to claim 6, wherein the functional substance is selected from an agricultural chemical, a medicament and a coloring material.

8. The production process according to claim 7, wherein the coloring material includes a pigment.

9. The production process according to claim 1, wherein the block polymer has a repeating structure of a monomer unit composed of an alkenyl ether.

10. An apparatus for producing a three-dimensionally structured material, which comprises a means for imparting a stimulus to a liquid composition comprising a block polymer and a liquid medium to modify the block polymer, thereby forming the three-dimensionally structured material.

11. A liquid composition suitable for use in producing a three-dimensionally structured material, which comprises a block polymer modifiable by stimulus and a liquid medium.

12. The liquid composition according to claim 11, wherein the block polymer is amphiphilic and forms micelles.

13. The liquid composition according to claim 11, wherein the block polymer has a repeating structure of a monomer unit composed of an alkenyl ether.

14. A three-dimensionally structured material formed by a block polymer modifiable by stimulus.
